(19) United States
(12) Patent Application Publication
(10) Pub. No.: US 2024/0389446 A1
(43) Pub. Date: Nov. 21, 2024

(54) DISPLAY DEVICE AND METHOD OF FABRICATING DISPLAY DEVICE

(71) Applicant: Samsung Display Co., LTD., Yongin-si (KR)

(72) Inventors: Je Won YOO, Yongin-si (KR); Young Ji KIM, Yongin-si (KR); Hyun KIM, Yongin-si (KR); Seung Min LEE, Yongin-si (KR)

(21) Appl. No.: 18/587,754

(22) Filed: Feb. 26, 2024

(30) Foreign Application Priority Data
May 17, 2023 (KR) 10-2023-0063577

(51) Int. Cl. H10K 77/10; H10K 59/12; H10K 102/00

(52) U.S. Cl. CPC H10K 77/10; H10K 59/1201; H10K 2102/311

(57) ABSTRACT

A display device includes: a first substrate having a first surface, a second surface opposite to the first surface, and a first side surface extending between the first surface and the second surface, the first substrate comprises a rigid material; a second substrate on the first surface of the first substrate and including a flexible material, the second substrate covering at least a part of the first side surface of the first substrate; and an emission material layer on the second substrate and including a plurality of light-emitting elements.

### CROSS-REFERENCE TO RELATED APPLICATION

The present application claims priority to and the benefit of Korean Patent Application No. 10-2023-0063577, filed on May 17, 2023, in the Korean Intellectual Property Office, the entire disclosure of which is incorporated herein by reference.

### BACKGROUND

### 1. Field

Aspects of embodiments of the present disclosure relate to a display device and a method of fabricating the same.

### 2. Description of the Related Art

As the information-oriented society evolves, various demands for display devices are increasing. Display devices may be flat panel display devices, such as a liquid-crystal display device, a field emission display device, and a light-emitting display device.

A display device generally has a display area where images are displayed and a non-display area around the display area. Recently, the width of the non-display area is ever decreasing for viewers to be more immersed in the content displayed in the display area and to increase the aesthetics of the display device.

Incidentally, in the process of fabricating a display device, the display device may be formed by cutting a mother substrate to separate a plurality of display cells formed thereon.

### SUMMARY

Embodiments of the present disclosure provide a display device having a reduced width of a non-display area and a method of fabricating the display device.

Embodiments of the present disclosure also provide a display device in which a thickness of a substrate can be reduced and the substrate can be cut and a method of fabricating the display device.

Embodiments of the present disclosure also provide a display device in which a cut portion or an edge of a substrate can be protected and a method of fabricating the display device.

It should be noted that aspects and features of the present disclosure are not limited to the above-mentioned aspects and features; and other aspects and features of the present disclosure will be apparent to those skilled in the art from the following descriptions.

According to an embodiment of the present disclosure, a display device includes: a first substrate having a first surface, a second surface opposite to the first surface, and a first side surface extending between the first surface and the second surface and including a rigid material, a second substrate on the first surface of the first substrate and including a flexible material, and an emission material layer on the second substrate and including a plurality of light-emitting elements. The second substrate covers at least a part of the first side surface of the first substrate.

In an embodiment, the first substrate may have a first inclined surface extending between the first side surface and the first surface.

In an embodiment, the second substrate may cover the first inclined surface of the first substrate.

In an embodiment, the first substrate may have a second side surface extending between the first surface and the second surface at an edge of a bending area where the second substrate is bent, and a shape of the first side surface may be different from a shape of the second side surface.

In an embodiment, the second substrate may not cover the second side surface.

In an embodiment, the second side surface may be an inclined surface, and an acute angle between the second side surface and the first surface may be greater than an acute angle between the first inclined surface and an extension direction of the first surface.

In an embodiment, an angle between the second side surface and the first surface may be an acute angle, and an angle between the second side surface and the second surface may be an obtuse angle.

In an embodiment, the first inclined surface may be along an edge of the first substrate, and the second side surface may be along an edge of the bending area.

In an embodiment, the first substrate may have an opening exposing the second substrate.

In an embodiment, the second substrate may cover at least a part of the second surface.

In an embodiment, an end of the second substrate may be on the second surface.

In an embodiment, the display device may further include an adhesive layer between the first side surface of the first substrate and the second substrate.

In an embodiment, an angle between the first side surface and the second surface may be 90 degrees.

In an embodiment, an end of the second substrate may be on the first side surface.

In an embodiment, a length of the second substrate in a direction may be greater than a length of the first substrate in the direction when they are flat.

According to an embodiment of the present disclosure, a method of fabricating a display device includes: preparing a first mother substrate having a first surface, a second surface opposite to the first surface, and a second mother substrate on the first surface; forming a plurality of display cells on the second mother substrate; forming grooves along borders of the display cells in the first mother substrate and the second mother substrate; forming a first substrate and a second substrate by spraying an etchant onto the second surface without a mask and cutting the first and second mother substrates along the grooves, the first substrate having a third surface, a fourth surface opposite to the first surface, and a first side surface extending between the third surface and the fourth surface, the second substrate having a protrusion protruding beyond the first side surface of the first substrate; and attaching the protrusion of the second substrate to the first side surface of the first substrate.

In an embodiment, the method may further include attaching a first protective film to the second surface other than a bending area where the second substrate is configured to be bent, and spraying the etchant onto the second surface to remove a part of the first mother substrate in the bending area.

In an embodiment, the first substrate may have a second side surface between the third surface and the fourth surface at an edge of the bending area, and a shape of the first side surface may be different from a shape of the second side surface.

In an embodiment, a depth of the grooves may be in a range of 0.5 to 0.8 times a thickness of the first mother substrate.

In an embodiment, a thickness of the first substrate after the spraying of the etchant may be smaller than a thickness of the first mother substrate before the spraying of the etchant.

According to an embodiment of the present disclosure, a width of a non-display area of a display device can be reduced.

According to an embodiment of the present disclosure, a thickness of a substrate of a display device can be reduced and the substrate can be accurately cut.

According to an embodiment of the present disclosure, a cut portion or an edge of a substrate can be protected.

It should be noted that aspects and features of the present disclosure are not limited to those described above and other aspects and features of the present disclosure will be apparent to those skilled in the art from the following descriptions.

### BRIEF DESCRIPTION OF THE DRAWINGS

The above and other aspects and features of the present disclosure will become more apparent by describing, in detail, embodiments thereof with reference to the attached drawings, in which:

FIG. 1 is a perspective view of a display device according to an embodiment of the present disclosure.

FIG. 2 is a plan view of a display panel and driver ICs shown in FIG. 1.

FIG. 3 is a perspective view of a display device according to another embodiment of the present disclosure.

FIG. 4 is a cross-sectional view of a display area of a display panel according to an embodiment of the present disclosure.

FIG. 5 is a cross-sectional view taken along the line X1-X1′ in FIG. 1.

FIG. 6 is a cross-sectional view of the display device shown in FIG. 5 in a bent configuration.

FIG. 7 is a cross-sectional view taken along the line X2-X2′ of FIG. 1.

FIG. 8 is a cross-sectional view of a display device taken along the line X2-X2′ of FIG. 1 according to another embodiment of the present disclosure.

FIG. 9 is a cross-sectional view of a display device taken along the line X2-X2′ of FIG. 1 according to another embodiment of the present disclosure.

FIG. 10 is a cross-sectional view of a display device taken along the line X2-X2′ of FIG. 1 according to another embodiment of the present disclosure.

FIG. 11 is a flowchart describing a method of fabricating a display device according to an embodiment of the present disclosure.

FIG. 12 is a perspective view illustrating step S100 of FIG. 11.

FIG. 13 is a cross-sectional view for illustrating step S100 of FIG. 11.

FIG. 14 is a perspective view for illustrating step S200 of FIG. 11.

FIGS. 15 to 18 are cross-sectional views for illustrating step S200 of FIG. 11.

FIG. 19 is a perspective view for illustrating step S300 of FIG. 11.

FIG. 20 is a cross-sectional view for illustrating step S300 of FIG. 11.

FIGS. 21 and 22 are perspective views for illustrating step S400 of FIG. 11.

FIGS. 23 to 25 are cross-sectional views for illustrating step S400 of FIG. 11.

FIG. 26 is a cross-sectional view for illustrating step S500 of FIG. 11.

FIG. 27 is a perspective view for illustrating step S600 of FIG. 11.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Hereinafter, embodiments of the present disclosure will be described, in detail, with reference to the accompanying drawings.

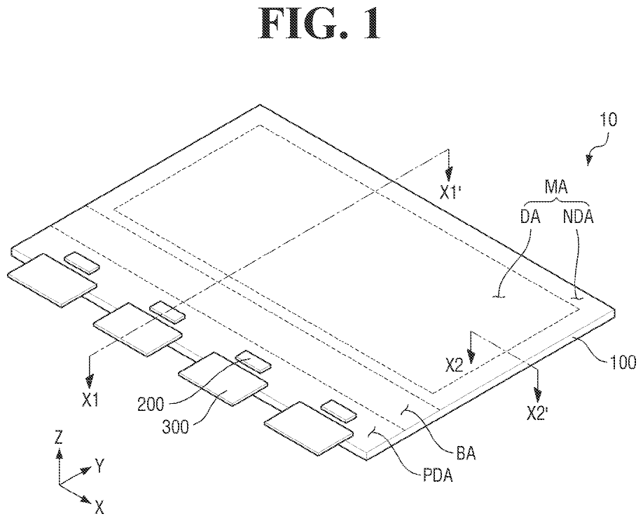

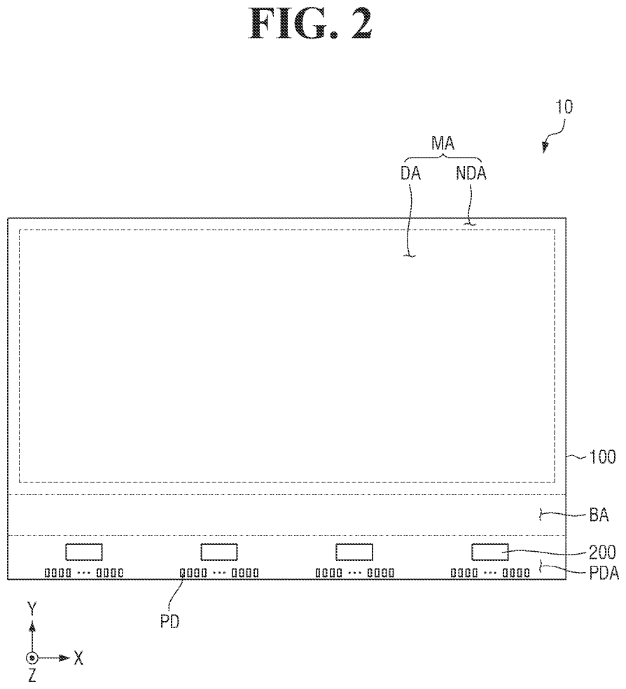

FIG. 1 is a perspective view of a display device according to an embodiment of the present disclosure. FIG. 2 is a plan view of a display panel and driver ICs shown in FIG. 1.

Referring to FIGS. 1 and 2, a display device 10, according to an embodiment of the present disclosure, is for displaying moving images and/or still images. The display device 10 may be used as a display screen of portable electronic devices, such as a mobile phone, a smart phone, a tablet PC, a smart watch, a watch phone, a mobile communications terminal, an electronic notebook, an electronic book, a portable multimedia player (PMP), a navigation device, and a ultra mobile PC (UMPC), as well as the display screen of various products, such as a television, a notebook, a monitor, a billboard, and an Internet of Things (IoT) device.

According to an embodiment of the present disclosure, the display device 10 may be a light-emitting display device, such as an organic light-emitting display device using organic light-emitting diodes, a quantum-dot light-emitting display device including a quantum-dot light-emitting layer, an inorganic light-emitting display device including an inorganic semiconductor, and a micro-LED display device using micro or nano light-emitting diodes (micro LEDs or nano LEDs). In the following description, an organic light-emitting display device is described as an example of the display device 10. It is, however, to be understood that the present disclosure is not limited thereto.

The display device 10, according to an embodiment, may include a display panel 100, driver integrated circuits (ICs) 200, and circuit boards 300.

The display panel 100 may be formed in a rectangular plane shape having longer sides in a first direction (e.g., an x-axis direction) and shorter sides in a second direction (e.g., y-axis direction) crossing (or intersecting) the first direction. Each of the corners at where the longer side in the first direction meets the shorter side in the second direction may be formed at a right angle or may be rounded with a curvature. The shape of the display panel 100, when viewed from the top (or in a plan view), is not limited to a quadrangular shape but may be a different polygonal shape, a circular shape, or an elliptical shape.

In the drawings, the first direction (e.g., the x-axis direction) and the second direction (e.g., the y-axis direction) cross each other as the horizontal directions. For example, the first direction and the second direction may be orthogonal to each other. In addition, the third direction (e.g., a z-axis direction) may cross (or intersect) the first direction (e.g., the x-axis direction) and the second direction (e.g., the y-axis direction) and may be, for example, a vertical direction orthogonal to them. Herein, the side indicated by the arrow of each of the first to third directions (e.g., the x-axis direction, y-axis direction, and z-axis direction) may be referred to as a first side while the opposite side may be referred to as a second side.

The display panel 100 may be flat, but the present disclosure is not limited thereto. For example, the display panel 100 may have left and right ends and may include a curved portion having a constant curvature or a varying curvature. In addition, the display panel 100 may be flexible so that it can be curved, bent, folded, or rolled.

The display panel 100 may have a main area MA, a bending area BA, and a pad area PDA. The main area MA may include a display area DA at where images are displayed and a non-display area NDA around the display area DA.

The display area DA may occupy most of the area of the display panel 100. The display area DA may be disposed at the center of display panel 100. Pixels, each including a plurality of emission areas, may be disposed to display images in the display area DA.

The non-display area NDA may be disposed adjacent to the display area DA. The non-display area NDA may be disposed on the outer side of the display area DA. The non-display area NDA may surround (e.g., may extend around a periphery of) the display area DA. The non-display area NDA may be defined as the border of the display panel 100.

The bending area BA may be located between the display area DA and the pad area PDA in the second direction (e.g., the y-axis direction). The bending area BA may extend in the first direction (e.g., the x-axis direction). The bending area BA may be bent such that it and the pad area PDA is located under the display panel 100. When the bending area BA is bent and located under the display panel 100, the plurality of driver ICs 200 and the circuit boards 300 may be located under the display panel 100.

The pad area PDA may be the lower edge area of the display panel 100. Display pads PD connected to the circuit boards 300 and first and second driving pads connected to the driver ICs 200 may be disposed in the pad area PDA.

In the pad area PDA, display pads DP may be disposed to be connected to the circuit boards 300. The display pads DP may be disposed at one edge of the display panel 100. For example, the display pads DP may be disposed at the lower edge of the display panel 100.

The driver integrated circuits (ICs) 200 may generate data voltages, supply voltages, scan timing signals, etc. The driver ICs 200 may output data voltages, supply voltages, scan timing signals, etc.

The driver ICs 200 may be disposed in the pad area PDA. The driver ICs 200 may be disposed between the display pads PD and the display area DA in the non-display area NDA. The driver ICs 200 may be attached to the non-display area NDA of the display panel 100 by a chip on glass (COG) technique. In another embodiment, the driver ICs 200 may be attached to the circuit boards 300, respectively, by a chip on plastic (COP) technique.

The circuit boards 300 may be disposed on the display pads DP disposed at one edge of the display panel 100. The circuit boards 300 may be attached to the display pads PD using a conductive adhesive member, such as an anisotropic conductive film and an anisotropic conductive adhesive. Accordingly, the circuit boards 300 may be electrically connected to signal lines of the display panel 100. The circuit boards 300 may be flexible printed circuit boards or flexible films, such as chip on films.

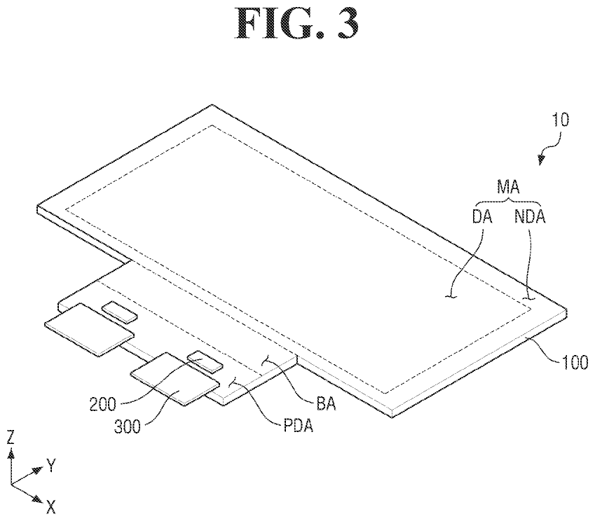

FIG. 3 is a perspective view of a display device according to another embodiment of the present disclosure.

Referring to FIG. 3, the shape of the display panel 100 according to this embodiment may be different from the shape of the display panel 100 according to the embodiment described above with reference to FIGS. 1 and 2.

For example, in the display panel 100 according to this embodiment, the length of the main area MA may be longer than the lengths of the bending area BA and the pad area PDA in the first direction (e.g., the x-axis direction). The bending area BA and the pad area PDA may protrude from a portion of one side of the main area MA.

The shape of the display panel 100 is not limited to the shapes shown in FIGS. 1 to 3 but various shapes may be applied depending on the type of display device 10.

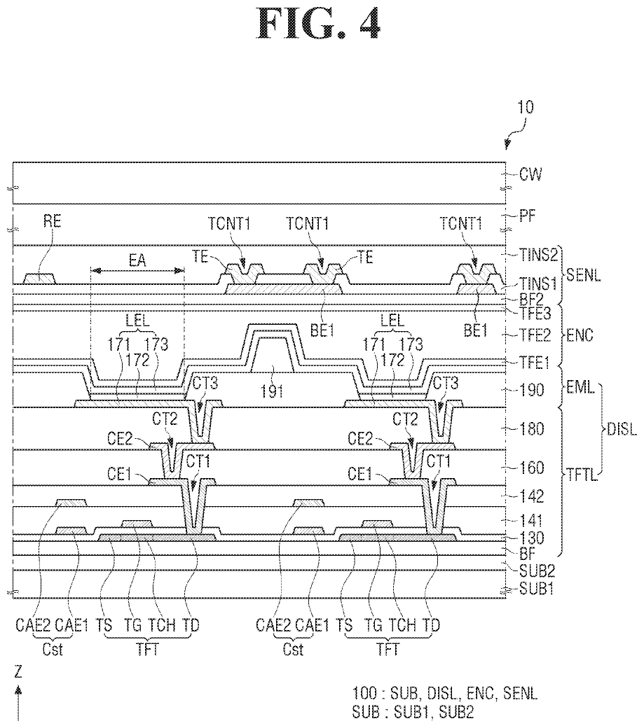

FIG. 4 is a cross-sectional view of a display area of a display device according to an embodiment of the present disclosure.

Referring to FIG. 4, the display device 10 may include a display panel 100, a polarizing film PF, and a cover window CW.

The display panel 100 may be an organic light-emitting display panel including light-emitting elements LEL, each including an emissive layer 172. It should be understood, however, that the present disclosure is not limited thereto. The display panel 100 may be a light-emitting display panel, such as a quantum-dot light-emitting display panel including a quantum-dot emissive layer, an inorganic light-emitting display panel including an inorganic semiconductor, and a micro light-emitting display panel using micro or nano light-emitting diodes (micro LEDs or nano LEDs). In the following description, an organic light-emitting display panel is described as an example of the display panel 100.

The display panel 100 may include a substrate SUB, a display layer DISL, an encapsulation layer ENC, and a sensor electrode layer SENL.

The substrate SUB may include a first substrate SUB1 made of a rigid material and a second substrate SUB2 made of a flexible polymer resin.

The first substrate SUB1 may include a rigid material. For example, the first substrate SUB1 may be made of glass. The first substrate SUB1 may be formed of ultra-thin glass (UTG) having a thickness of approximately 200 μm or less.

The second substrate SUB2 may include a flexible material. The second substrate SUB2 may be made of a polymer resin having a thickness smaller than that of the first substrate SUB1. For example, the second substrate SUB2 may have a thickness of approximately 20 μm. The second substrate SUB2 may be formed of an organic material, such as an acryl resin, an epoxy resin, a phenolic resin, a polyamide resin and a polyimide resin. When the second substrate SUB2 is made of a polymer resin, it may be referred to as a plastic substrate.

The display layer DISL may include a thin-film transistor layer TFTL including a plurality of thin-film transistors and an emission material layer EML including a plurality of light-emitting elements.

The thin-film transistor layer TFTL may include a buffer film BF, a thin-film transistor TFT, a gate insulator 130, a first interlayer dielectric film 141, a capacitor Cst, a second interlayer dielectric film 142, a first data metal layer, a first organic film 160, a second data metal layer, and a second organic film 180.

A buffer film BF may be disposed on the substrate SUB. The buffer film BF may be formed of an inorganic material, such as a silicon nitride layer, a silicon oxynitride layer, a silicon oxide layer, a titanium oxide layer, and an aluminum oxide layer. In some embodiments, the buffer film BF may be made up of multiple layers in which two or more of a silicon nitride layer, a silicon oxynitride layer, a silicon oxide layer, a titanium oxide layer, and an aluminum oxide layer are stacked on one another.

An active layer including a channel region TCH, a source region TS, and a drain region TD of the thin-film transistor TFT may be disposed on the buffer film BF. The active layer may be made of polycrystalline silicon, monocrystalline, low-temperature polycrystalline silicon, amorphous silicon, or an oxide semiconductor. When the active layer includes polycrystalline silicon or an oxide semiconductor material, the source region TS and the drain region TD in the active layer may be conductive regions doped with ions or impurities to have conductivity.

A gate insulator 130 may be disposed on the active layer of the thin-film transistor TFT. The gate insulator 130 may be formed of an inorganic layer, for example, a silicon nitride layer, a silicon oxynitride layer, a silicon oxide layer, a titanium oxide layer, or an aluminum oxide layer.

A first gate metal layer including a gate electrode TG of the thin-film transistor TFT, a first capacitor electrode CAE1 of a capacitor Cst, and scan lines may be disposed on the gate insulator 130. The gate electrode TG of the thin-film transistor TFT may overlap the channel region TCH in the third direction (e.g., the z-axis direction). The first gate metal layer may be made up of a single layer or multiple layers of one of molybdenum (Mo), aluminum (Al), chromium (Cr), gold (Au), titanium (Ti), nickel (Ni), neodymium (Nd), copper (Cu), and an alloy thereof.

The first interlayer dielectric film 141 may be disposed on the first gate metal layer. The first interlayer dielectric film 141 may be formed of an inorganic layer, for example, a silicon nitride layer, a silicon oxynitride layer, a silicon oxide layer, a titanium oxide layer, or an aluminum oxide layer. The first interlayer dielectric film 141 may include a plurality of inorganic layers.

The second gate metal layer including a second capacitor electrode CAE2 of the capacitor Cst may be disposed on the first interlayer dielectric film 141. The second capacitor electrode CAE2 may overlap the first capacitor electrode CAE1 in the third direction (e.g., the z-axis direction). Therefore, the capacitor Cst may be formed by the first capacitor electrode CAE1, the second capacitor electrode CAE2, and an inorganic insulating dielectric film disposed therebetween and acting as a dielectric film. The second gate metal layer may be made up of a single layer or multiple layers of one of molybdenum (Mo), aluminum (Al), chromium (Cr), gold (Au), titanium (Ti), nickel (Ni), neodymium (Nd), copper (Cu), and an alloy thereof.

A second interlayer dielectric film 142 may be disposed on the second gate metal layer. The second interlayer dielectric film 142 may be formed of an inorganic layer, for example, a silicon nitride layer, a silicon oxynitride layer, a silicon oxide layer, a titanium oxide layer, or an aluminum oxide layer. The second interlayer dielectric film 142 may include a plurality of inorganic layers.

The first data metal layer including first connection electrodes CE1 and data lines may be disposed on the second interlayer dielectric film 142. The first connection electrode CE1 may be connected to the drain region TD through a first contact hole (e.g., a first contact opening) CT1 penetrating (or extending through) the gate insulator 130, the first interlayer dielectric film 141, and the second interlayer dielectric film 142. The first data metal layer may be made up of a single layer or multiple layers of one of molybdenum (Mo), aluminum (Al), chromium (Cr), gold (Au), titanium (Ti), nickel (Ni), neodymium (Nd), copper (Cu), and an alloy thereof.

A first organic film 160 may be disposed over the first connection electrode CE1 to provide a flat surface over the thin-film transistors TFT, which have uneven heights. The first organic film 160 may be formed as an organic layer, such as an acryl resin, an epoxy resin, a phenolic resin, a polyamide resin, and a polyimide resin.

A second data metal layer including second connection electrodes CE2 may be disposed on the first organic film 160. The second data metal layer may be connected to the first connection electrode CE1 through a second contact hole (e.g., a second contact opening) CT2 penetrating (or extending through) the first organic film 160. The second data metal layer may be made up of a single layer or multiple layers of one of molybdenum (Mo), aluminum (Al), chromium (Cr), gold (Au), titanium (Ti), nickel (Ni), neodymium (Nd), copper (Cu), and an alloy thereof.

The second organic film 180 may be disposed on the second connection electrode CE2. The second organic film 180 may be formed as an organic layer, such as an acryl resin, an epoxy resin, a phenolic resin, a polyamide resin, and a polyimide resin.

In some embodiments, the second data metal layer including the second connection electrodes CE2 and the second organic film 180 may be omitted.

The emission material layer EML is disposed on the thin-film transistor layer TFTL. The emission material layer EML may include light-emitting elements LEL and a bank 190.

Each of the light-emitting elements LEL may include a pixel electrode 171, an emissive layer 172, and a common electrode 173. In each of the emission areas EA, the pixel electrode 171, the emissive layer 172, and the common electrode 173 are stacked on one another sequentially so that holes from the pixel electrode 171 and electrons from the common electrode 173 are combined with each other in the emissive layer 172 to emit light. In such an embodiment, the pixel electrode 171 may be an anode electrode while the common electrode 173 may be a cathode electrode.

A pixel electrode layer including the pixel electrode 171 may be formed on the second organic film 180. The pixel electrode 171 may be connected to the second connection electrode CE2 through a third contact hole (e.g., a third contact opening) CT3 penetrating (or extending through) the second organic film 180. The pixel electrode layer may be made up of a single layer or multiple layers of one of molybdenum (Mo), aluminum (Al), chromium (Cr), gold (Au), titanium (Ti), nickel (Ni), neodymium (Nd), copper (Cu), and an alloy thereof.

In a top-emission structure where light exits from the emissive layer 172 toward the common electrode 173, the pixel electrode 171 may be made up of a single layer of molybdenum (Mo), titanium (Ti), copper (Cu), or aluminum (Al) or may be made up of a stack structure of aluminum and titanium (Ti/Al/Ti), a stack structure of aluminum and ITO (ITO/Al/ITO), an APC alloy, and a stack structure of APC alloy and ITO (ITO/APC/ITO) to increase the reflectivity. The APC alloy is an alloy of silver (Ag), palladium (Pd), and copper (Cu).

The bank 190 may define the emission areas EA of the pixels. To this end, the bank 190 may be formed on the second organic film 180 to expose a part of the pixel electrode 171. The bank 190 may cover the edges of the pixel electrode 171. The bank 190 may be disposed inside the third contact hole CT3. In other words, the third contact hole CT3 may be filled with the bank 190. The bank 190 may be formed of an organic layer, such as an acryl resin, an epoxy resin, a phenolic resin, a polyamide resin, and a polyimide resin.

A spacer 191 may be disposed on the bank 190. The spacer 191 may support a mask during a process of fabricating the emissive layer 172. The spacer 191 may be an organic layer made of, for example, an acryl resin, an epoxy resin, a phenolic resin, a polyamide resin, and a polyimide resin.

The emissive layer 172 is formed on the pixel electrode 171. The emissive layer 172 may include an organic material configured to emit light of a certain color. For example, the emissive layer 172 may include a hole transporting layer, an organic material layer, and an electron transporting layer. The organic material layer may include a host and a dopant. The organic material layer may include a material that emits a light (e.g., a predetermined light or light having a certain color) and may be formed by using a phosphor or a fluorescent material.

The common electrode 173 is formed on the emissive layer 172. The common electrode 173 may be formed to cover the emissive layer 172. The common electrode 173 may be a common layer formed across the emission areas EA1, EA2, EA3, and EA4. A capping layer may be formed on the common electrode 173.

In the top-emission structure, the common electrode 173 may be formed of a transparent conductive material, such as ITO and IZO, that can transmit light, or a semi-transmissive conductive material, such as magnesium (Mg), silver (Ag), and an alloy of magnesium (Mg) and silver (Ag). When the common electrode 173 is formed of a semi-transmissive metal material, the light extraction efficiency can be increased by forming microcavities.

The encapsulation layer ENC may be disposed on the emission material layer EML. The encapsulation layer ENC may include one or more inorganic films TFE1 and TFE3 to prevent permeation of oxygen or moisture into the emission material layer EML. In addition, the encapsulation layer ENC may include at least one organic film to protect the emission material layer EML from particles, such as dust. For example, the encapsulation layer ENC may include a first inorganic encapsulation film TFE1, an organic encapsulation film TFE2, and a second inorganic encapsulation film TFE3.

The first inorganic encapsulation film TFE1 may be disposed on the common electrode 173, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer, and an aluminum oxide layer are alternately stacked on one another. The organic encapsulation film TFE2 may be an organic film, such as an acryl resin, an epoxy resin, a phenolic resin, a polyamide resin, a polyimide resin, etc.

The sensor electrode layer SENL may be disposed on the encapsulation layer ENC. The sensor electrode layer SENL may include a second buffer film BF2, a first bridge BE1, a first sensor insulating film TINS1, sensor electrodes TE and RE, and a second sensor insulating film TINS2.

The second buffer film BF2 may be disposed on the encapsulation layer ENC. The second buffer film BF2 may include at least one inorganic film. For example, the second buffer film BF2 may be made up of multiple layers in which one or more inorganic layers of a silicon nitride layer, a silicon oxynitride layer, a silicon oxide layer, a titanium oxide layer, and an aluminum oxide layer are alternately stacked on one another. In some embodiments, the second buffer film BF2 may be omitted.

The first bridges BE1 may be disposed on the second buffer film BF2. The first bridges BE1 may be made up of a single layer of molybdenum (Mo), titanium (Ti), copper (Cu), or aluminum (Al) or may have a stack structure of aluminum and titanium (Ti/Al/Ti), a stack structure of aluminum and ITO (ITO/Al/ITO), an APC alloy, and a stack structure of an APC alloy and ITO (ITO/APC/ITO).

The first sensor insulating film TINS1 may be disposed on the first bridges BE1. The first sensor insulating film TINS1 may be formed of an inorganic layer, for example, a silicon nitride layer, a silicon oxynitride layer, a silicon oxide layer, a titanium oxide layer, or an aluminum oxide layer.

The sensor electrodes (e.g., the driving electrodes TE and sensing electrodes RE) may be disposed on the first sensor insulating film TINS1. In addition, dummy patterns may be disposed on the first sensor insulating film TNIS1. The driving electrodes TE, the sensing electrodes RE and the dummy patterns do not overlap (e.g., are offset from) the emission areas EA. The driving electrodes TE, the sensing electrodes RE, and the dummy patterns may be made up of a single layer of molybdenum (Mo), titanium (Ti), copper (Cu), or aluminum (Al) or may have a stack structure of aluminum and titanium (Ti/Al/Ti), a stack structure of aluminum and ITO (ITO/Al/ITO), an APC alloy, and a stack structure of an APC alloy and ITO (ITO/APC/ITO).

The second sensor insulating film TINS2 may be disposed on the driving electrodes TE, the sensing electrodes RE, and the dummy patterns. The second sensor insulating film TINS2 may include at least one of an inorganic film and an organic film. The inorganic film may be a silicon nitride layer, a silicon oxynitride layer, a silicon oxide layer, a titanium oxide layer, or an aluminum oxide layer. The organic film may be an acryl resin, an epoxy resin, a phenolic resin, a polyamide resin, and a polyimide resin.

The polarizing film PF may be disposed on the sensor electrode layer SENL. The polarizing film PF may be disposed on the display panel 100 to reduce reflection of external light. The polarizing film PF may include a first base member, a linear polarizer, a retardation film, such as λ/4 (quarter-wave) plate, and a second base member. The first base member, the retardation film, the linear polarizer, and the second base member of the polarizing film PF may be sequentially stacked on the display panel 100.

The cover window CW may be disposed on the polarizing film PF. The cover window CW may be attached onto the polarizing film PF by a transparent adhesive member, such as an optically clear adhesive (OCA) film.

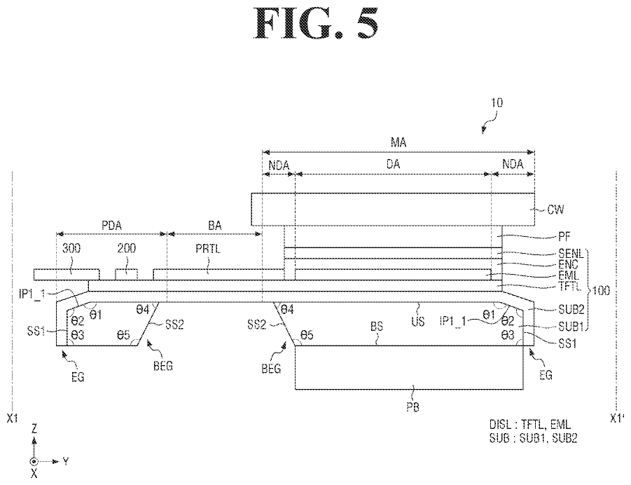

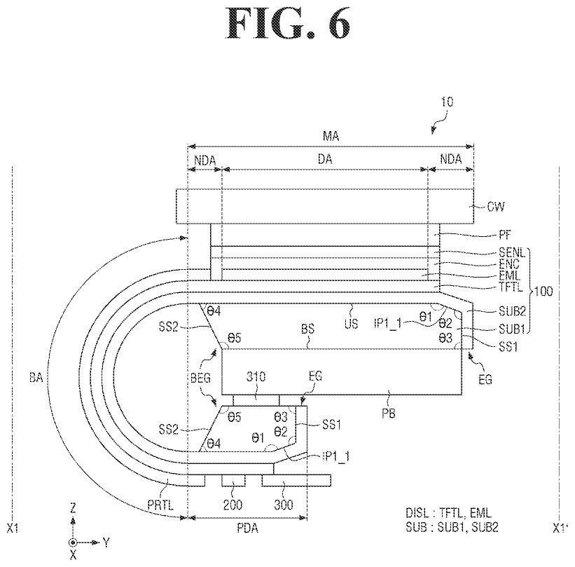

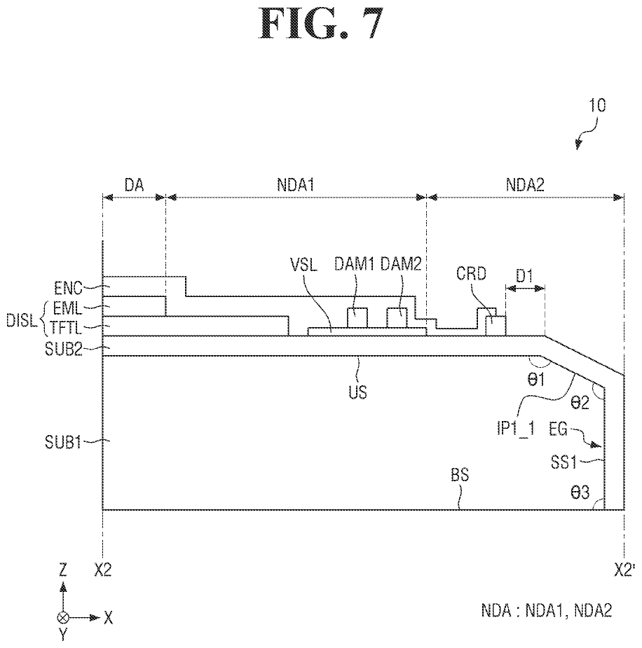

FIG. 5 is a cross-sectional view taken along the line X1-X1′ in FIG. 1. FIG. 6 is a cross-sectional view of the display device shown in FIG. 5 in a bent configuration. FIG. 7 is a cross-sectional view taken along the line X2-X2′ of FIG. 1. The side of the substrate SUB on the left side in FIGS. 5 and 6 may be the lower side of the display device 10 as shown in FIG. 1. The side of the substrate SUB on the right side in FIGS. 5 and 6 may be the upper side of the display device 10 as shown in in FIG. 1. The side of the substrate SUB on the right side in FIG. 7 may be the right side of the display device 10 as shown in FIG. 1. Because the left side of the display device 10 as shown in FIG. 1 may be substantially identical to the right side, it is not depicted.

Referring to FIGS. 5 to 7, the display device 10 may further include a protective film PRTL and a panel bottom cover PB, in addition to the substrate SUB, the display panel 100, the polarizing film PF, the cover window CW, the driver IC 200, and the circuit board 300.

The substrate SUB may include the first substrate SUB1 made of a rigid material and the second substrate SUB2 made of a flexible polymer resin.

The first substrate SUB1 may be a rigid material. For example, the first substrate SUB1 may be made of glass. The first substrate SUB1 may be formed of ultra-thin glass (UTG) having a thickness of approximately 200 μm or less.

The second substrate SUB2 may be made of a polymer resin having a thickness smaller than that of the first substrate SUB1. For example, the second substrate SUB2 may have a thickness of approximately 20 μm. The second substrate SUB2 may be formed of an organic material, such as an acryl resin, an epoxy resin, a phenolic resin, a polyamide resin, and a polyimide resin. When the second substrate SUB2 is made of a polymer resin, it may be referred to as a plastic substrate.

The first substrate SUB1 may not be disposed in the bending area BA. For example, the first substrate SUB1 may have an opening exposing the second substrate SUB2 in the bending area BA. Because the bending area BA includes the second substrate SUB2 having a flexible material and does not include the first substrate SUB1, it can be easily bent as shown in FIG. 6.

The display layer DISL may be disposed on a first surface of the substrate SUB. The display layer DISL may display images. The display layer DISL may include the thin-film transistor layer TFTL in which thin-film transistors are formed and the emission material layer EML in which light-emitting elements that emit light are disposed in the emission areas.

In the display area DA of the display layer DISL, scan lines, data lines, voltage lines, etc. may be disposed so that lights are emitted in the emission areas. In the non-display area NDA of the display layer DISL, a scan driver circuit for outputting scan signals to the scan lines, fan-out lines connecting the data lines with the driver ICs 200, etc. may be disposed.

The protective layer PRTL may be disposed on the thin-film transistor layer TFTL in the bending area BA. The protective layer PRTL may be a layer for protecting the thin-film transistor layer TFTL exposed to the outside in the bending area BA. The protective layer PRTL may be formed of an organic material, such as an acryl resin, an epoxy resin, a phenolic resin, a polyamide resin, and a polyimide resin.

The encapsulation layer ENC may encapsulate the emission material layer of the display layer DISL to prevent oxygen or moisture from permeating into the emission material layer of the display layer DISL. The encapsulation layer ENC may be disposed on the display layer DISL. The encapsulation layer ENC may be disposed on the upper and side surfaces of the display layer DISL. The encapsulation layer ENC may be disposed to cover the display layer DISL.

The sensor electrode layer SENL may be disposed on the display layer DISL. The sensor electrode layer SENL may include sensor electrodes. The sensor electrode layer SENL is configured to sense a user's touch by using the sensor electrodes.

The polarizing film PF may be disposed on the sensor electrode layer SENL. The polarizing film PF may be disposed on the display panel 100 to reduce reflection of external light. The polarizing film PF may include a first base member, a linear polarizer, a retardation film, such as λ/4 (quarter-wave) plate, and a second base member. The first base member, the retardation film, the linear polarizer, and the second base member of the polarizing film PF may be sequentially stacked on the display panel 100.

The cover window CW may be disposed on the polarizing film PF. The cover window CW may be attached onto the polarizing film PF by a transparent adhesive member, such as an optically clear adhesive (OCA) film.

The panel bottom cover PB may be disposed on a second surface of the substrate SUB of the display panel 100. The second surface of the substrate SUB may be opposite to the first surface. The panel bottom cover PB may be attached to the second surface of the substrate SUB of the display panel 100 by an adhesive member. The adhesive member may be a pressure-sensitive adhesive (PSA).

The panel bottom cover PB may include at least one of: a light-blocking member for absorbing light incident from outside, a buffer member for absorbing external impact, and a heat dissipating member for efficiently discharging heat from the display panel 100.

The driver IC 200 and the circuit board 300 may be bent such that they are located under the display panel 100, as shown in FIG. 6. The circuit board 300 may be attached to the lower surface of the panel bottom cover PB by an adhesive member 310. The adhesive member 310 may be a pressure-sensitive adhesive.

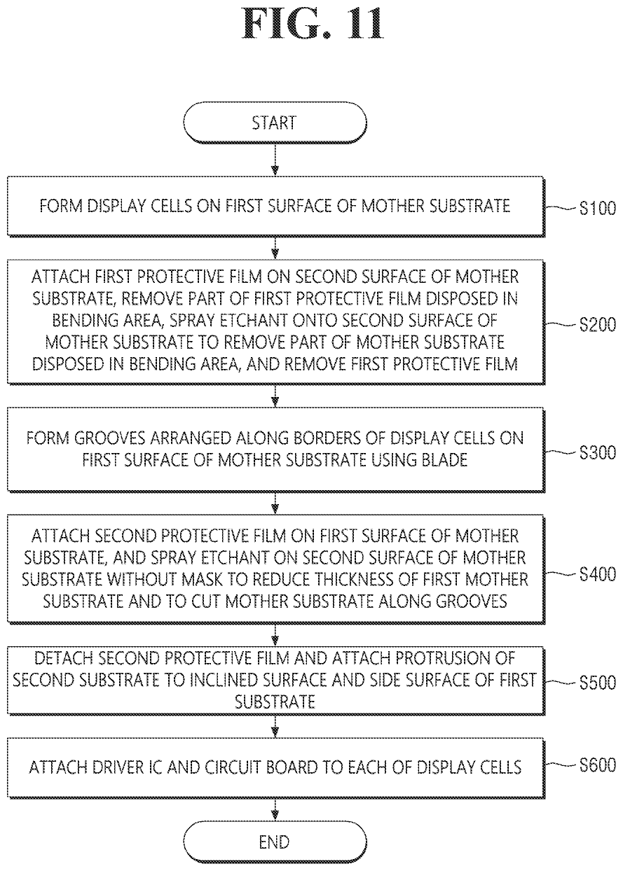

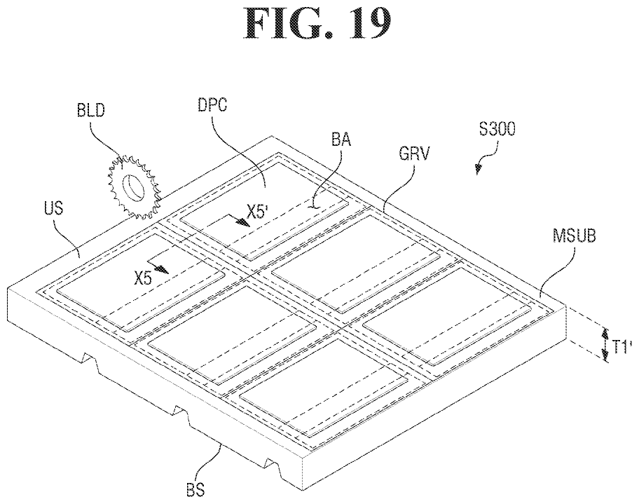

The display device 10, according to this embodiment, may have inclined surfaces at edges EG of the display panel 100 and edges BEG of the bending area BA. The inclined surfaces at the edges EG of the display panel 100 may be formed by forming grooves GRV (see, e.g., FIG. 19) and then spraying an etchant to cut the substrate SUB of the display panel 100 according to a method of fabricating a display device, to be described later (see, e.g., FIG. 11). The inclined surfaces at the edges BEG of the bending area BA may be formed by etching the first substrate SUB1 of the bending area BA according to the method of fabricating a display device, to be described later.

The first substrate SUB1 may have an upper surface US, a bottom surface BS, a first side surface SS1, and a first inclined surface IP1_1. The upper surface US of the first substrate SUB1 may be a side surface in the third direction (e.g., the z-axis direction), and the bottom surface BS may be the opposite side surface in the third direction (e.g., the z-axis direction).

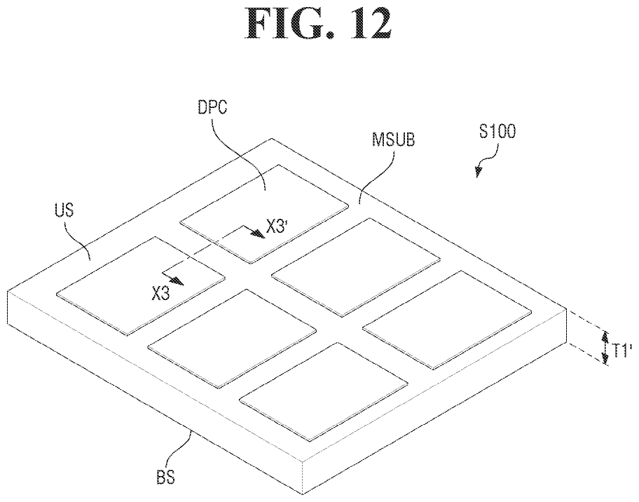

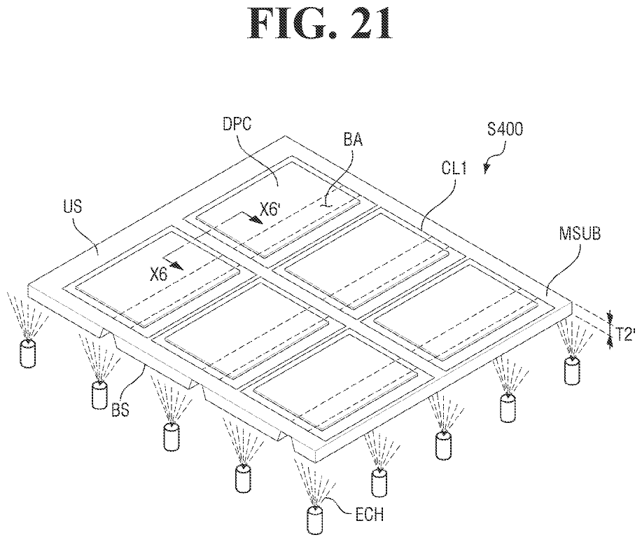

The first side surface SS1 may be located between (or may extend between) the upper surface US and the bottom surface BS. The first side surface SS1 may be positioned at an edge EG of the display panel 100. According to an embodiment of the present disclosure, the first side surface SS1 may be extended such that it is perpendicular to the upper surface US and the bottom surface BS. An angle 63 formed between the first side surface SS1 and the bottom surface BS may be approximately 90°. The edge EG of the display panel 100 may be refer to the edge that is cut along a first cutting line CL1 (see, e.g., FIG. 21) between a plurality of adjacent display cells DPC (see, e.g., FIG. 12) according to the method of fabricating a display device (see, e.g., FIG. 11).

The first inclined surface IP1_1 may be located between the upper surface US and the first side surface SS1. The first inclined surface IP1_1 may be formed by forming the grooves GRV (see, e.g., FIG. 19) and then spraying the etchant to cut it. The first inclined surface IP1_1 may be formed due to the isotropic nature of wet etching.

An angle 61 between the first inclined surface IP1_1 and the upper surface US may be an obtuse angle. An angle 62 between the first inclined surface IP1_1 and the first side surface SS1 may be an obtuse angle. For example, the angle 61 between the first inclined surface IP1_1 and the upper surface US and the angle 62 formed between the first inclined surface IP1_1 and the first side surface SS1 may be equal to or greater than about 135°.

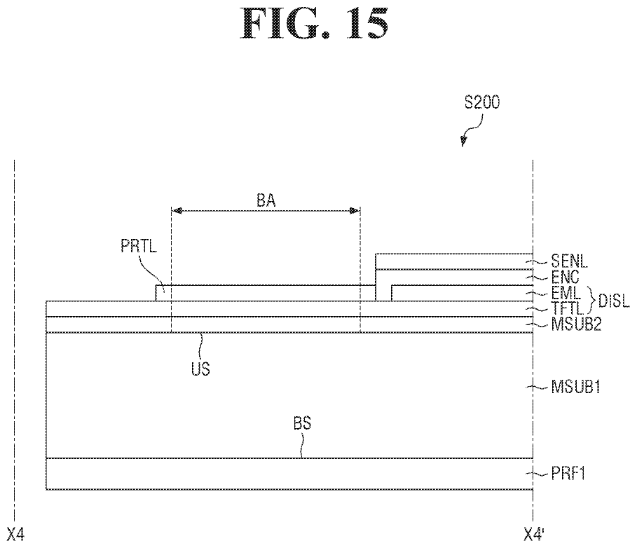

The first substrate SUB1 may have a second side surface SS2 adjacent to the bending area BA. The second side surface SS2 may be positioned at the edge BEG of the bending area BA. The second side surface SS2 may be formed by attaching a first protective film PRF1 (see, e.g., FIG. 15) to etch a part of the bending area BA according to the method of fabricating a display device, to be described later (see, e.g., FIG. 11). The edge BEG of the bending area BA may refer to an edge formed by etching the first substrate SUB1 on the bending area BA according to the method of fabricating a display device.

The second side surface SS2 may be an inclined surface. For example, an angle 64 between the second side surface SS2 and the upper surface US may be an acute angle. An angle 65 formed between the second side surface SS2 and the bottom surface BS may be an obtuse angle.

The cross-sectional shape of the substrate SUB at the edge BEG of the bending area BA may be different from the cross-sectional shape of the substrate SUB at the edge EG of the display panel 100.

According to an embodiment of the present disclosure, the edge EG of the display panel 100 may have two surfaces extending in different directions between the upper surface US and the bottom surface BS, that is, the first inclined surface IP1_1 and the first side surface SS1. On the other hand, the edge BEG of the bending area BA may include only one surface, that is, the inclined second side surface SS2.

In some embodiments, the acute angle 64 formed between the second side surface SS2 and the upper surface US may be greater than an acute angle formed between the first inclined surface IP1_1 and the upper surface US. For example, the acute angle 64 formed between the second side surface SS2 and the upper surface US may be greater than a value obtained by subtracting the angle 61 between the first inclined surface IP1_1 and the upper surface from 180°.

According to this embodiment, the second substrate SUB2 may cover the first inclined surface IP1_1 and the first side surface SS1 of the first substrate SUB1 at the edge EG of the display panel 100. The second substrate SUB2 may be bent along the first inclined surface IP1_1 and the first side surface SS1. The second substrate SUB2 may be formed of a flexible material so that it may be easily bent along the first inclined surface IP1_1 and the first side surface SS1. When the second substrate SUB2 is in the form of a very thin film, it may be attached to the first substrate SUB1 by electrostatic force.

As such, when the second substrate SUB2 covers the first inclined surface IP1_1 and the first side surface SS1 of the first substrate SUB1, it can protect the side surface of the first substrate SUB1 from external impact. In addition, because it is not necessary to perform an additional polishing process on the side surface in such an embodiment to mitigate externa, impact, the process efficiency can be increased.

At the edge BEG of the bending area BA, the second substrate SUB2 may not cover the second side surface SS2 of the first substrate SUB1. The second side surface SS2 may be exposed to the outside without being covered by the second substrate SUB2.

Incidentally, as shown in FIG. 7, the display device 10 may further include a first supply voltage line VSL, a first dam DAM1, a second dam DAM2, and a crack dam CRD disposed on the non-display area NDA.

The non-display area NDA may include a first non-display area NDA1 on a side of the display area DA, and a second non-display area NDA2 on a side of the first non-display area NDA1. Structures for driving pixels of the display area DA may be disposed in the first non-display area NDA1. The second non-display area NDA2 may be disposed on the outer side of the first non-display area NDA1. The second non-display area NDA2 may be an edge area of the non-display area NDA. In addition, the second non-display area NDA2 may be an edge area of the display panel 100.

The first supply voltage line VSL, the first dam DAM1, and the second dam DAM2 may be disposed in the first non-display area NDA1. The first supply voltage line VSL may extend in the second direction (e.g., the y-axis direction) in the non-display area NDA on the left and right sides of the display panel 100. The first supply voltage line VSL may be electrically connected to the common electrode 173 (see, e.g., FIG. 4), and accordingly, the common electrode 173 (see, e.g., FIG. 4) may receive a first supply voltage from the first supply voltage line VSL.

The first dam DAM1 and the second dam DAM2 are structures for preventing the organic encapsulation film TFE2 (see, e.g., FIG. 4) of the encapsulation layer ENC from overflowing to the edge EG of the display panel 100. The first dam DAM1 and the second dam DAM2 may extend in the second direction (e.g., the y-axis direction) in the non-display area NDA on the left and right sides of the display panel 100. The second dam DAM2 may be disposed on the outer side of the first dam DAM1. The first dam DAM1 may be disposed closer to the display area DA than the second dam DAM2 is, and the second dam DAM2 may be disposed closer to the edge EG of the display panel 100 than the first dam DAM1 is.

Although the first dam DAM1 and the second dam DAM2 are disposed on the first supply voltage line VSL in the embodiment shown in FIG. 7, the present disclosure is not limited thereto. For example, one of the first dam DAM1 and the second dam DAM2 may not be disposed on the first supply voltage line VSL. In another embodiment, none of the first dam DAM1 and the second dam DAM2 may be disposed on the first supply voltage line VSL. In such an embodiment, the first dam DAM1 and the second dam DAM2 may be disposed on the outer side of the first supply voltage line VSL1.

In addition, although the display panel 100 includes the two dams DAM1 and DAM2 according to the embodiment shown in FIG. 7, the present disclosure is not limited thereto. In some embodiments, a display panel 100 may include three or more dams.

The crack dam CRD may be disposed in the second non-display area NDA2. The crack dam CRD may be a structure for preventing cracks from occurring during a process of cutting the substrate SUB in the process of fabricating the display device 10. The crack dam CRD may be the outermost structure disposed at the outermost position on the left and right sides of the display panel 100. The crack dam CRD may extend in the second direction (e.g., y-axis direction) in the non-display area NDA on the left and right sides of the display panel 100.

In the display device 10 according to this embodiment, by forming the grooves GRV and then spraying an etchant to cut the substrate SUB of the display panel 100 (see, e.g., FIG. 19) according to the method of fabricating a display device (see, e.g., FIG. 11), a distance D1 from the crack dam CRD to the edge EG of the display panel 100 may be reduced. For example, the distance D1 between the crack dam CRD and the first inclined surface IP1_1 may be approximately 30 μm or less. The distance D1 between the crack dam CRD and the first inclined surface IP1_1 may be about 0 μm. Accordingly, the width of the second non-display area NDA2, that is, the width of the non-display area NDA, can be reduced.

Hereinafter, display devices according to other embodiments of the present disclosure will be described. In the following description, the same or similar elements will be denoted by the same or similar reference numerals, and redundant descriptions of such elements will be omitted or briefly described.

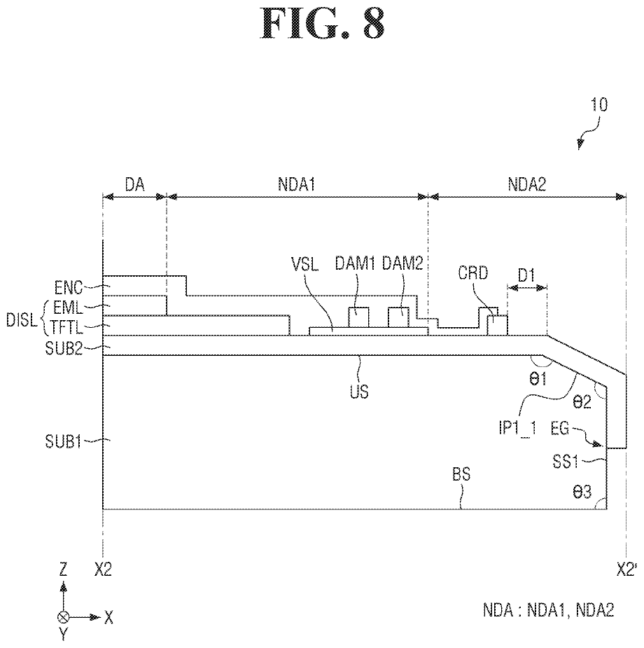

FIG. 8 is a cross-sectional view of a display device according to another embodiment of the present disclosure.

A display device 10 according to the embodiment shown in FIG. 8 is different from the display device 10 according to the embodiment shown in FIG. 7 in that a second substrate SUB2 covers only a part of a first side surface SS1 of a first substrate SUB1.

More specifically, in the display device 10 according to this embodiment, the second substrate SUB2 may cover a portion of the first side surface SS1 of the first substrate SUB1. For example, the second substrate SUB2 may completely cover the first inclined surface IP1_1 but may only partially cover the first side surface SS1. One end of the second substrate SUB2 may be positioned on the first side surface SS1.

Because the substrate is bent at the boundary where the upper surface US and the first inclined surface IP1_1 of the first substrate SUB1 meet each other, the boundary where the first inclined surface IP1_1 and the first side surface SS1 meet each other the boundaries may be vulnerable to external impact. Therefore, according to this embodiment, the boundary between the upper surface US and the first inclined surface IP1_1 of the first substrate SUB1 and the boundary between the first inclined surface IP1_1 and the first side surface SS1 are completely covered by the second substrate SUB2, while a part of the first side surface SS1 may be covered by the second substrate and the remaining part may not be covered by it.

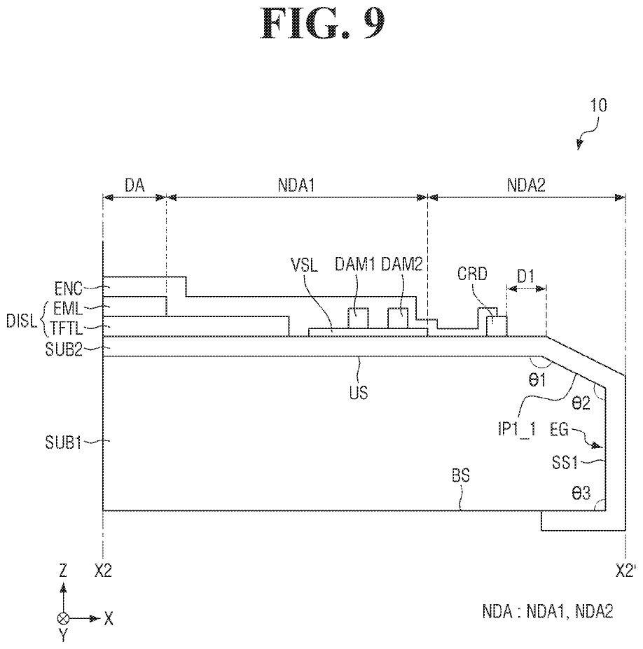

FIG. 9 is a cross-sectional view of a display device according to another embodiment of the present disclosure.

A display device 10 according to the embodiment shown in FIG. 9 is different from the display devices 10 according to the embodiments shown in FIGS. 7 and 8 in that a second substrate SUB2 also covers a bottom surface BS of a first substrate SUB1.

More specifically, in the display device 10 according to this embodiment, the second substrate SUB2 may cover the bottom surface BS of the first substrate SUB1. For example, the second substrate SUB2 may completely cover the first inclined surface IP1_1 and the first side surface SS1 and may further cover a part of the bottom surface BS. One end of the second substrate SUB2 may be positioned on the bottom surface BS.

Because the first substrate SUB1 is bent at the boundary where the first side surface SS1 and the bottom surface BS meet each other, the boundary may be vulnerable to external impact. Therefore, according to this embodiment, the boundary where the first side surface SS1 and the bottom surface BS of the first substrate SUB1 meet each other may be completely covered by the second substrate SUB2.

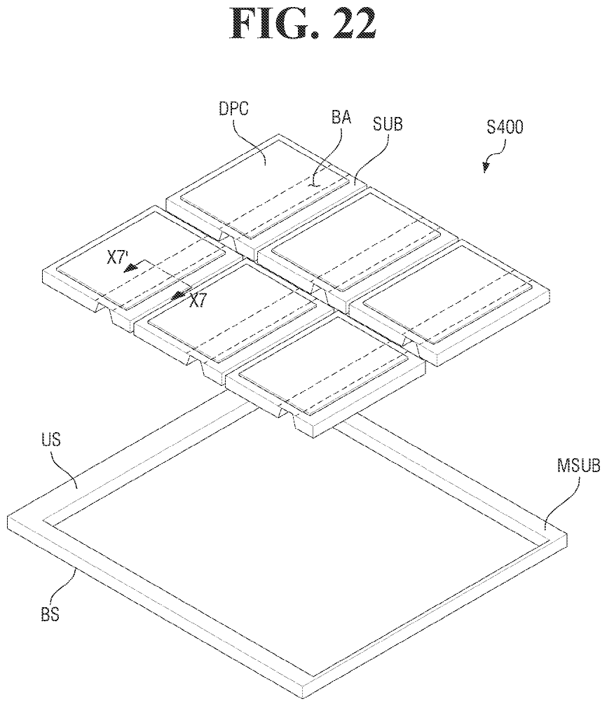

As described with reference to FIGS. 8 and 9, the length of the second substrate SUB2 covering the first side surface SS1 of the first substrate SUB1 may be variously adjusted by adjusting the etching degree of the first substrate SUB1 according to the method of fabricating a display device (see, e.g., FIG. 11). This will be described later with reference to FIGS. 22 to 24.

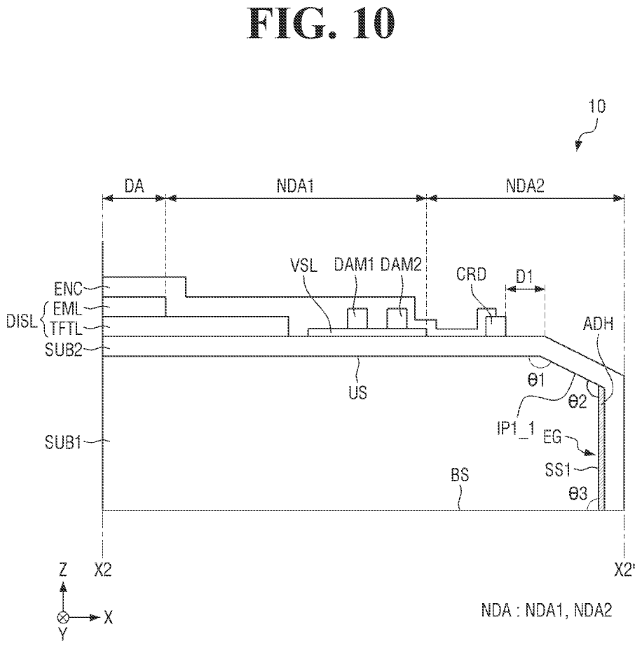

FIG. 10 is a cross-sectional view of a display device according to another embodiment of the present disclosure.

A display device 10 according to the embodiment shown in FIG. 10 is different from the display device 10 according to the embodiment shown in FIG. 7 in that an adhesive layer ADH is interposed between a first substrate SUB1 and a second substrate SUB2.

More specifically, the display device 10 according to this embodiment may further include the adhesive layer ADH interposed between the first substrate SUB1 and the second substrate SUB2.

According to this embodiment of the present disclosure, as shown in FIG. 10, the adhesive layer ADH may be interposed between the first side surface SS1 of the first substrate SUB1 and the second substrate SUB2. According to another embodiment, the adhesive layer ADH may be interposed between the first inclined surface IP1_1 and the second substrate SUB2. According to another embodiment, the adhesive layer ADH may be disposed over the entire surface between the first substrate SUB1 and the second substrate SUB2.

The adhesive layer ADH may include at least one of: an optically clear adhesive film (OCA), an optically clear resin (OCR), and a pressure sensitive adhesive film (PSA). As another example, the adhesive layer ADH may include at least one of light-cured adhesives and heat-cured adhesives.

Different from the display device 10 according to the embodiment described above with reference to FIG. 7 in which the second substrate SUB2 is attached to the first substrate SUB1 by using electrostatic force, the display device 10 according to this embodiment in which the adhesive layer ADH is interposed between the first substrate SUB1 and the second substrate SUB2 can provide improved adhesion. In addition, by attaching an adhesive layer ADH having a shock-absorbing feature, it is possible to more reliably protect the side surface of the first substrate SUB1.

Incidentally, in FIG. 10, similar to the display device 10 according to the embodiment described above with reference to FIG. 7, the second substrate SUB2 completely covers the side surface of the first substrate SUB1, and one end of the second substrate SUB2 is aligned with the bottom surface BS of the first substrate SUB1. It should be understood, however, that the present disclosure is not limited thereto. That is to say, the adhesive layer ADH may be interposed between the first substrate SUB1 and the second substrate SUB2 in the embodiments described above with reference to FIGS. 8 and 9 as well.

Hereinafter, a method of fabricating the display device according to the above-described embodiments of the present disclosure will be described.

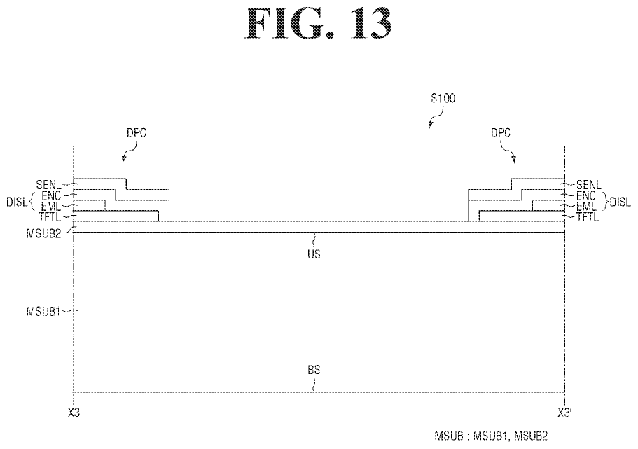

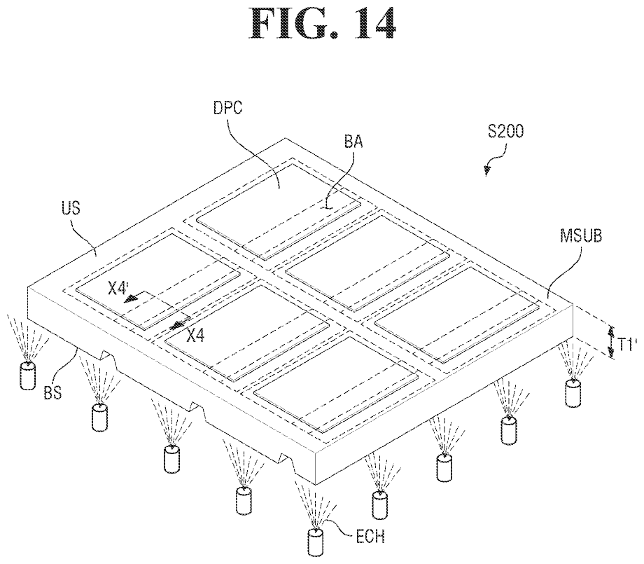

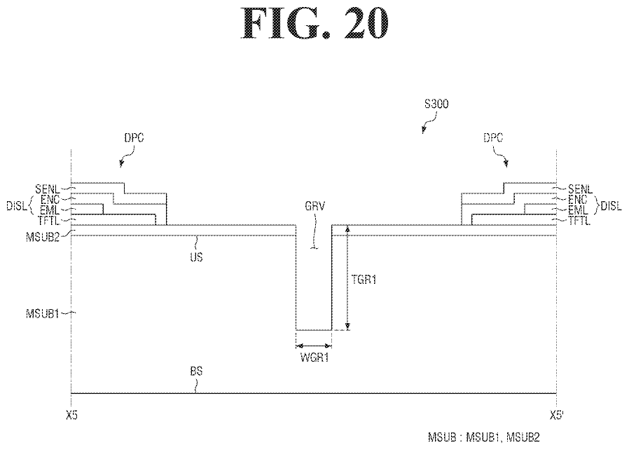

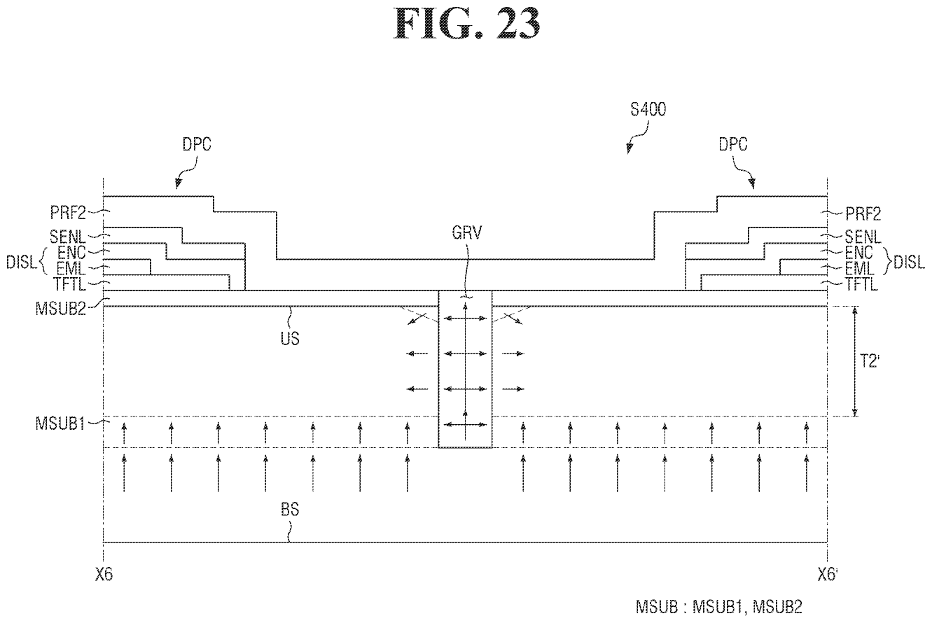

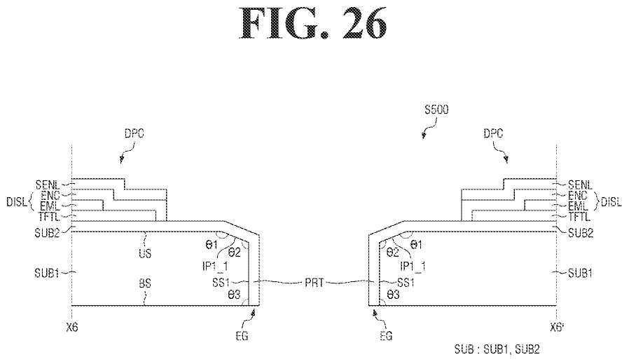

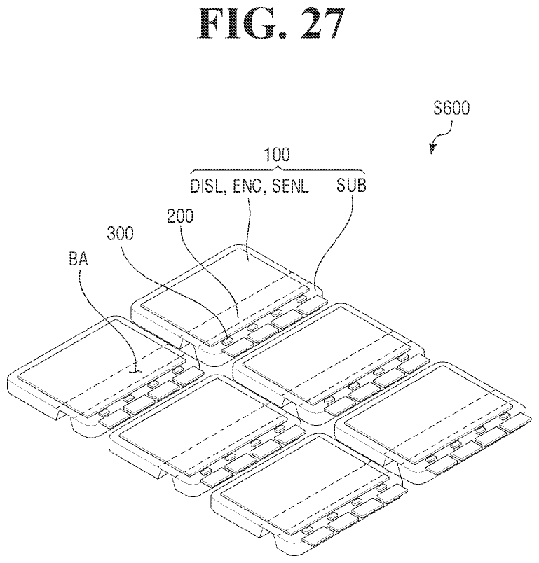

FIG. 11 is a flowchart describing a method of fabricating a display device according to an embodiment of the present disclosure. FIG. 12 is a perspective view for illustrating step S100 of the method described in FIG. 11. FIG. 13 is a cross-sectional view for illustrating step S100 of the method described in FIG. 11. FIG. 14 is a perspective view for illustrating step S200 of the method described in FIG. 11. FIGS. 15 to 18 are cross-sectional views for illustrating step S200 of FIG. 11. FIG. 19 is a perspective view for illustrating step S300 of the method described in FIG. 11. FIG. 20 is a cross-sectional view for illustrating step S300 of the method described in FIG. 11. FIGS. 21 and 22 are perspective views for illustrating step S400 of the method described in FIG. 11. FIGS. 23 to 25 are cross-sectional views for illustrating step S400 of the method described in FIG. 11. FIG. 26 is a cross-sectional view for illustrating step S500 of the method described in FIG. 11. FIG. 27 is a perspective view for illustrating step S600 of the method described in FIG. 11.

Referring to FIGS. 11 to 27, a method of fabricating a display device according to an embodiment, firstly, may include, forming a plurality of display cells on a first surface of a mother substrate (step S100 of FIG. 11) as shown in FIGS. 12 and 13.

A mother substrate MSUB may include a first mother substrate MSUB1 and a second mother substrate MSUB2. The first mother substrate MSUB1 may be made of a rigid material. The second mother substrate MSUB2 may be made of a flexible material.

Each of the display cells DPC may include the first mother substrate MSUB1, the second mother substrate MSUB2 disposed on the upper surface US of the first mother substrate MSUB1, the display layer DISL disposed on the second mother substrate MSUB2, the encapsulation layer ENC disposed on the display layer DISL, and the sensor electrode layer SENL disposed on the encapsulation layer ENC. The display layer DISL may include the thin-film transistor layer TFTL, and the emission material layer EML.

Secondly, as shown in FIGS. 14 to 18, a first protective film may be attached to a second surface (e.g., a bottom surface) of a mother substrate, a part of the first protective film disposed in the bending area may be removed, an etchant may be sprayed onto the second surface of the mother substrate to remove a part of the mother substrate disposed in the bending area, and the first protective film may be removed (step S200 of FIG. 11).

Initially, the first protective film PRF1 may be attached to the rear surface of the mother substrate MSUB, that is, the bottom surface BS of the first mother substrate MSUB1. The first protective film PRF1 may be an acid-resistant film. The first protective film PRF1 can prevent the first mother substrate MSUB1 from being etched where the first protective film PRF1 is attached (see, e.g., FIG. 15).

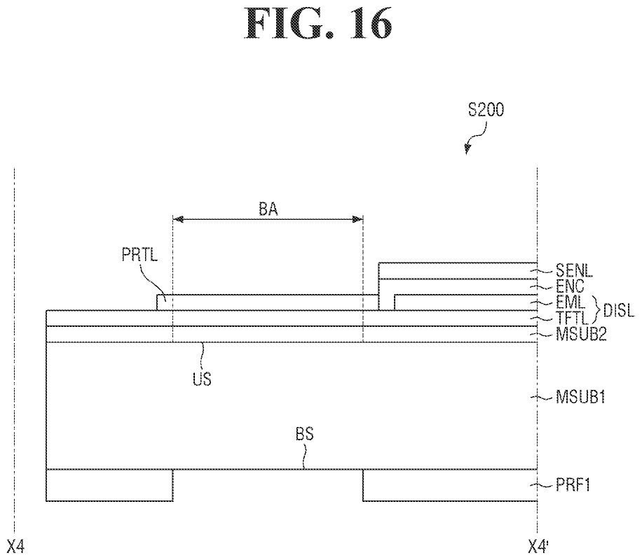

Subsequently, the first protective film PRF1 disposed in the bending area BA may be removed (see, e.g., FIG. 16). The bottom surface BS of the first mother substrate MSUB1 may be exposed in the bending area BA where the first protective film PRF1 is removed.

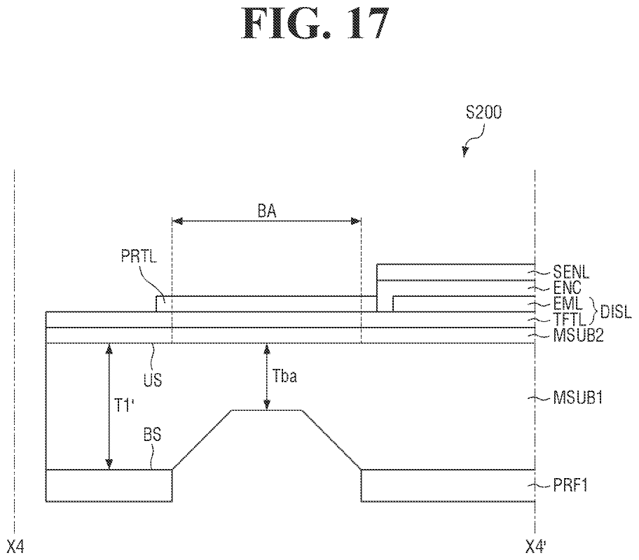

Subsequently, an etchant is sprayed onto the bottom surface BS of the first mother substrate MSUB1 to etch out a part of the first mother substrate MSUB1 disposed in the bending area BA (see, e.g., FIG. 14). By doing so, a part of the first mother substrate MSUB1 disposed in the bending area BA may be removed (see, e.g., FIG. 17). A thickness Tba of the first mother substrate MSUB1 in the bending area BA may be smaller than the first thickness T1′ of the first mother substrate MSUB1 in areas other than the bending area BA.

After a part of the first mother substrate MSUB1 is etched, inclined surfaces may be formed in the bending area BA. Such inclined surfaces may be formed by the isotropic nature of wet etching.

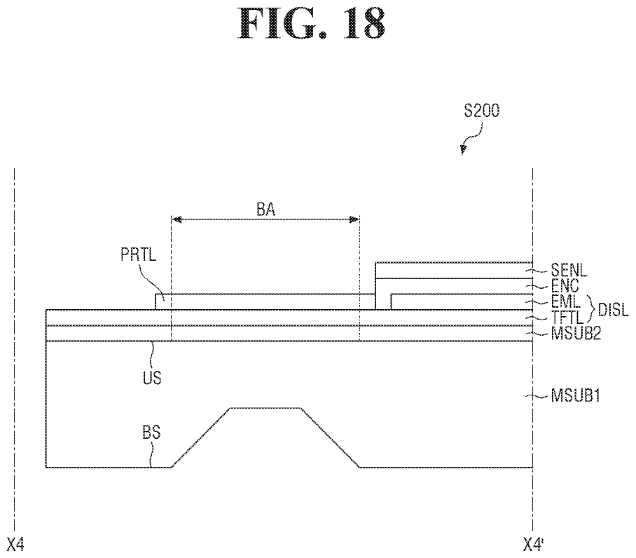

Subsequently, the first protective film PRF1 may be removed (see, e.g., FIG. 18).

Thirdly, as shown in FIGS. 19 and 20, grooves may be formed in the first surface of the mother substrate along the borders of the plurality of display cells by using a blade (step S300 of FIG. 11).

The blade BLD may form the grooves GRV from the upper surface US toward the bottom surface BS of the mother substrate MSUB (see, e.g., FIGS. 19 and 20). For example, the blade BLD may dice (or cut) the second mother substrate MSUB2 and the first mother substrate MSUB1 together (e.g., simultaneously). The blade BLD may dice the mother substrate MSUB along the borders of the plurality of display cells DPC. Accordingly, the grooves GRV may be formed along the borders of the plurality of display cells DPC.

The depth TGR1 of the grooves GRV may be in a range of approximately 0.5 to approximately 0.8 times the first thickness T1′ of the first mother substrate MSUB1. For example, the first thickness T1′ of the first mother substrate MSUB1 may be approximately 500 μm. The depth TGR1 of the grooves GRV may be in a range of approximately 250 μm to approximately 400 μm. The width WGR1 of the grooves GRV may be in a range of approximately 50 μm to approximately 200 μm.

Although the cross-sectional shape of the grooves GRV is shown as being rectangular in the drawings, it is not limited thereto. For example, the cross-sectional shape of the grooves GRV may be a polygon, such as a triangle and a trapezoid, or may have a curved line shape, such as a ‘U’ shape.

Fourthly, as shown in FIGS. 21 to 25, a second protective film may be attached to the first surface of the mother substrate, and an etchant may be sprayed onto the second surface of the mother substrate without a mask so that the thickness of the first mother substrate can be reduced and the mother substrate can be cut along the grooves (step S400 of FIG. 11).

Initially, a second protective film PRF2 may be attached to the upper surface US of the mother substrate MSUB. The second protective film PRF2 may cover all of the plurality of display cells DPC together. The second protective film PRF2 may cover the plurality of display cells DPC, the second mother substrate MSUB2, and the grooves GRV (see, e.g., FIG. 23). The second protective film PRF2 may be an acid-resistant film. The second protective film PRF2 can protect the plurality of display cells DPC from an etchant ECH in a process of etching the mother substrate MSUB.

Subsequently, the etchant ECH may be sprayed onto the bottom surface BS of the first mother substrate MSUB1 without a mask to reduce the thickness of the first mother substrate MSUB1 and to cut the mother substrate MSUB along the grooves GRV (see, e.g., FIGS. 21 and 23).

By spraying the etchant onto the bottom surface BS of the first mother substrate MSUB1, the first thickness T1′ of the first mother substrate MSUB1 can be reduced to the second thickness T2′. The first thickness T1′ may be approximately 500 μm, and the second thickness T2′ may be approximately 200 μm.

Because the first mother substrate MSUB1 is etched without a mask, the entire bottom surface BS of the first mother substrate MSUB1 can be etched uniformly (e.g., isotropic etching).

As the thickness of the first mother substrate MSUB1 gradually decreases, the etchant ECH may penetrate into the grooves GRV from the point where the bottom surface BS meets the grooves GRV. Accordingly, while etching proceeds on the bottom surface BS, isotropic etching may also proceed inside the grooves GRV in both horizontal directions.

In doing so, the first mother substrate MSUB1 including an inorganic material may be etched by the etchant ECH, but the second mother substrate MSUB2 including an organic material may not be etched. In addition, on the surface at where the first mother substrate MSUB1 and the second mother substrate MSUB2 are in contact with each other (e.g., on the upper surface of the first mother substrate MSUB1), anisotropic etching may proceed in a diagonal direction different from the horizontal directions due to differences in physical properties between the first mother substrate MSUB1 and the second mother substrate MSUB2, surface tension, etc.

After the etching process is completed, a first cutting line CL1 may be formed (see, e.g., FIG. 21). Each of the plurality of display cells DPC may be separated from the mother substrate MSUB along the first cutting line CL1.

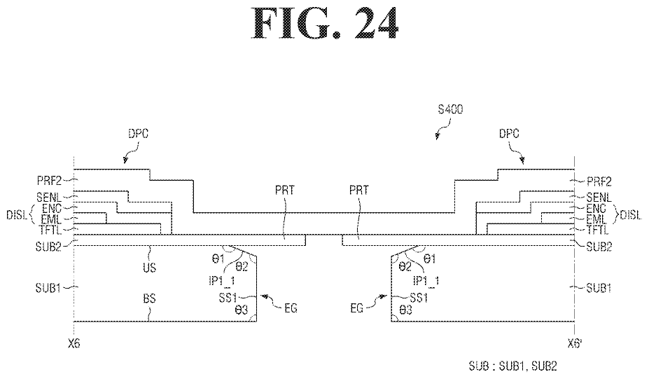

The first substrate SUB1 separated from the mother substrate MSUB along the first cutting line CL1 may have a first inclined surface IP1_1 between the first side surface SS1 and the upper surface US at the edge EG of the plurality of display cells DPC (see, e.g., FIG. 24). The second substrate SUB2 separated from the mother substrate MSUB along the first cutting line CL1 may have a protrusion PRT. The protrusion PRT of the second substrate SUB2 may protrude from (e.g., may protrude beyond) the side surface of the first substrate SUB1. The length of the protrusion PRT may be adjusted by adjusting the depth TGR1 and width WGR1 of the grooves GRV, the etching rate and the etching degree, etc.

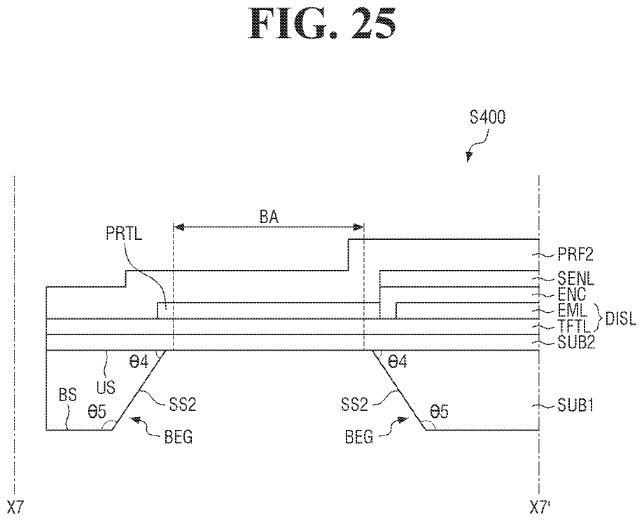

Incidentally, the first mother substrate MSUB1 may be etched also in the bending area BA. The first mother substrate MSUB1 having the inclined surfaces shown in FIG. 18 is etched, and the second side surfaces SS2 may be finally formed at the edges BEG of the bending area BA, as shown in FIG. 25. As described above with reference to, for example, FIG. 5, the shape of the second side surface SS2 at the edge BEG of the bending area BA may be different from the shape of the first side surface SS1 and the first inclined surface IP1_1 at the edge EG of the display cells DPC.

Fifthly, as shown in FIG. 26, the second protective film may be detached, and the protrusion of the second substrate may be attached to the inclined surface and side surface of the first substrate (step S500 of FIG. 11).

After the etching process is completed, the second protective film PRF2 may be detached and removed.

The protrusion PRT of the second substrate SUB2 may be bent along the first inclined surface IP1_1 and the first side surface SS1 of the first substrate SUB1. The protrusion PRT of the second substrate SUB2 may be attached to the first inclined surface IP1_1 and the first side surface SS1 of the first substrate SUB1.

Sixthly, as shown in FIG. 27, a driver IC and a circuit board may be attached to each of the plurality of display cells (step S500 of FIG. 11).

The driver IC 200 and the circuit board 300 may be attached to each of the plurality of display cells DPC. The driver IC 200 and the circuit board 300 may be attached to a pad area located at one side of the bending area BA.

According to the method of fabricating a display device of this embodiment, the yield of the process of cutting the mother substrate MSUB may be improved. For example, if the first mother substrate MSUB1 and the second mother substrate MSUB2 are cut completely together using a blade BLD or a laser, the mother substrate MSUB may not be cut as desired due to the overall (or excessive) thickness. In contrast, according to the method of fabricating a display device according to this embodiment, the grooves GRV are formed in the first mother substrate MSUB1 and the second mother substrate MSUB2, and then, the first mother substrate MSUB1 is etched so that the thickness of the mother substrate MSUB is reduced and the first mother substrate MSUB1 and the second mother substrate MSUB2 may be cut together (e.g., simultaneously). As a result, the process efficiency can be increased. In addition, the yield of the process of cutting the substrates may be improved because they can be cut as desired, compared to the process of completely cutting the first mother substrate MSUB1 and the second mother substrate MSUB2 at once using a blade BLD or laser.

In addition, according to the method of fabricating a display device according to this embodiment, the second substrate SUB2 may cover the first inclined surface IP1_1 and the first side surface SS1 of the first substrate SUB1 at the edge EG of the display cells DPC. As such, because the second substrate SUB2 covers the first inclined surface IP1_1 and the first side surface SS1 of the first substrate SUB1, it can protect the side surface of the first substrate SUB1 from external impact. In addition, because an additional polishing process on the side surface does not need to be performed to mitigate external impact, the process efficiency can be increased.

In concluding the detailed description, those skilled in the art will appreciate that many variations and modifications can be made to the embodiments described herein without substantially departing from the present disclosure. Therefore, the described embodiments of the present disclosure are used in a generic and descriptive sense and not for purposes of limitation.

What is claimed is:

1. A display device comprising:
a first substrate having a first surface, a second surface opposite to the first surface, and a first side surface extending between the first surface and the second surface, the first substrate comprises a rigid material;
a second substrate on the first surface of the first substrate and comprising a flexible material, the second substrate covering at least a part of the first side surface of the first substrate; and
an emission material layer on the second substrate and comprising a plurality of light-emitting elements.

2. The display device of claim 1, wherein the first substrate has a first inclined surface extending between the first side surface and the first surface.

3. The display device of claim 2, wherein the second substrate covers the first inclined surface.

4. The display device of claim 2, wherein the first substrate has a second side surface extending between the first surface and the second surface at an edge of a bending area where the second substrate is bent, and
wherein a shape of the first side surface is different from a shape of the second side surface.

5. The display device of claim 4, wherein the second substrate does not cover the second side surface.

6. The display device of claim 4, wherein the second side surface is an inclined surface, and
wherein an acute angle between the second side surface and the first surface is greater than an acute angle between the first inclined surface and an extension direction of the first surface.

7. The display device of claim 4, wherein an angle between the second side surface and the first surface is an acute angle, and
wherein an angle between the second side surface and the second surface is an obtuse angle.

8. The display device of claim 4, wherein the first inclined surface extends along an edge of the first substrate, and
wherein the second side surface extends along an edge of the bending area.

9. The display device of claim 1, wherein the first substrate has an opening exposing the second substrate.

10. The display device of claim 1, wherein the second substrate covers at least a part of the second surface of the first substrate.

11. The display device of claim 10, wherein an end of the second substrate is on the second surface.

12. The display device of claim 1, further comprising an adhesive layer between the first side surface of the first substrate and the second substrate.

13. The display device of claim 1, wherein an angle between the first side surface and the second surface is 90 degrees.

14. The display device of claim 1, wherein an end of the second substrate is on the first side surface.

15. The display device of claim 1, wherein a total length of the second substrate is greater than a total length of the first substrate.

16. A method of fabricating a display device, the method comprising:
preparing a first mother substrate having a first surface and a second surface opposite to the first surface, and a second mother substrate on the first surface of the first substrate;
forming a plurality of display cells on the second mother substrate;
forming grooves along borders of the display cells in the first mother substrate and the second mother substrate;
forming a first substrate and a second substrate by spraying an etchant onto the second surface of the first mother substrate without a mask and cutting the first and second mother substrates along the grooves, the first substrate having a third surface, a fourth surface opposite to the first surface, and a first side surface extending between the third surface and the fourth surface, the second substrate having a protrusion protruding beyond the first side surface of the first substrate; and
attaching the protrusion of the second substrate to the first side surface of the first substrate.

17. The method of claim 16, further comprising attaching a first protective film to the second surface outside of a bending area where the second substrate is configured to be bent, and spraying the etchant onto the second surface to remove a part of the first mother substrate in the bending area.

18. The method of claim 17, wherein the first substrate has a second side surface extending between the third surface and the fourth surface at an edge of the bending area, and
wherein a shape of the first side surface is different from a shape of the second side surface.

19. The method of claim 16, wherein a depth of the grooves is in a range of 0.5 to 0.8 times a thickness of the first mother substrate.

20. The method of claim 16, wherein a thickness of the first substrate after the spraying of the etchant is smaller than a thickness of the first mother substrate before the spraying of the etchant.
